(19) United States
(12) Patent Application Publication
(10) Pub. No.: US 2014/0061907 A1
(43) Pub. Date: Mar. 6, 2014

(54) SEMICONDUCTOR DEVICE AND METHOD FOR FORMING THE SAME

(71) Applicant: SK Hynix Inc, Icheon (KR)

(72) Inventors: Eun Hye KWAK, Seoul (KR); Ki Soo CHOI, Cheongju (KR)

(73) Assignee: SK Hynix Inc, Icheon (KR)

(21) Appl. No.: 13/946,429

(22) Filed: Jul. 19, 2013

(30) Foreign Application Priority Data
Aug. 31, 2012 (KR) 10-2012-0096389

(51) Int. Cl. H01L 23/498; H01L 21/768

(52) U.S. Cl. CPC H01L 23/49816; H01L 21/76879
USPC 257/738; 438/666; 257/773

(57) ABSTRACT

A semiconductor device includes a metal line and a metal pad formed at different integration levels of a semiconductor substrate, and an isolation layer by which the metal line and the metal pad are spaced apart from each other. The semiconductor device prevents short-circuiting between the metal pad and the metal line although the isolation layer is dislocated.

### CROSS-REFERENCE TO RELATED APPLICATION

The priority of Korean patent application No. 10-2012-0096389 filed on 31 Aug. 2012, the disclosure of which is hereby incorporated by reference in its entirety, is claimed.

### BACKGROUND

Embodiments relate to a semiconductor device and a method for forming the same, and more particularly to a technology related to a semiconductor device for distributing a bonding pressure and a method for manufacturing the same.

In recent times, as information media such as computers have rapidly come into widespread use, technology of a semiconductor device has been rapidly developed. Functionally, it is necessary for a semiconductor device to operate at a high speed and to have a high storage capacity. Therefore, technology for manufacturing semiconductor devices has rapidly developed to improve an integration degree, reliability, a response speed, etc.

A process for manufacturing semiconductor devices includes (i) a fabrication (FAB) process that forms cells, each having integrated circuits, by stacking predetermined circuit patterns on a silicon substrate, and (ii) an assembly process that packages the substrate into unit cells. An Electrical Die Sorting (EDS) process for testing electrical characteristics of cells formed over the substrate is performed between the FAB process and the assembly process.

In more detail, a conductive layer of a semiconductor device is formed by stacking a metal layer and an insulation layer, and is manufactured by interconnecting an upper conductive layer and a lower conductive layer. As the semiconductor device becomes miniaturized and more highly integrated, the number of stacked conductive layers is increased, and the number of insulation layers to be stacked and patterned increases accordingly. A bonding pad connected to a lead frame is formed at the end stage of the above fabrication processes.

FIG. 1 is a cross-sectional view illustrating a conventional semiconductor device according to the related art.

Referring to FIG. 1, a conventional semiconductor device includes at least one lower metal line 12 formed over a semiconductor substrate 10, an interlayer insulation film 14 provided between the lower metal lines 12, a protective film 16 formed over the lower metal line 12 and the interlayer insulation film 14, an interlayer insulation film 18 formed over the protective film 16, and a metal contact 20 that passes through the interlayer insulation film 18 and the protective film 16 and is connected to the lower metal line 12.

In addition, the semiconductor device includes a metal pad 22 and a metal line 23 formed over the interlayer insulation film 18, an isolation pattern 24 formed to insulate between the metal pad 22 and the metal line 23, an isolation layer 28 connected to the isolation pattern 24 and formed over a protective film 26, and a passivation layer 30 formed over the isolation layer 28.

In this case, spacing between the metal pad 22 and the metal line 23 is gradually reduced in proportion to the increasing integration degree of the semiconductor device. The isolation patterns 24 may be laterally dislocated by as much as denoted ‘A’ due to a bonding pressure imposed when a package ball adheres to the metal pad 22, making the metal pad 22 electrically short-circuited to the metal line 23.

### SUMMARY

Various embodiments are directed to providing a semiconductor device and a method for forming the same to address problems of the related art.

An embodiment relates to a semiconductor device for solving the above problem that a metal pad is electrically connected to a metal line to result in the occurrence of short-circuiting because isolation patterns are spaced apart from each other by a bonding pressure generated when a package ball adheres to a pad.

In accordance with an aspect of the embodiment, a semiconductor device includes: a first metal pad and a second metal pad spaced apart from each other and provided over an interlayer insulation film of a semiconductor substrate; a trench disposed between the first metal pad and the second metal pad and provided in the interlayer insulation film; and a metal line formed in the trench.

The semiconductor device may further include: an isolation layer formed over the metal line, and disposed between the first metal pad and the second metal pad.

The semiconductor device may further include: a first metal contact formed to pass through the interlayer insulation film and coupled to the first metal pad.

The semiconductor device may further include: a second metal contact formed to pass through the interlayer insulation film and coupled to the second metal pad.

The semiconductor device may further include: a first lower line connected to a lower part of the first metal contact.

The semiconductor device may further include: a second lower line coupled to a lower portion of the second metal contact.

The semiconductor device may further include: a third metal contact formed between the metal line and a surface of the trench.

The isolation layer may include an insulation film formed using a High Density Plasma (HDP) process.

The semiconductor device may further include: a passivation layer formed over the isolation layer.

The passivation layer may include a Polymide Isoindro Quirazorindione (PIQ) layer.

The semiconductor device may further include: a bonding region formed to expose an end of the first metal pad and an end of the second metal pad and provided at both sides of the isolation layer.

Each of the first metal pad and the second metal pad is provided at a different level from a metal line, wherein each of the first metal pad and the second metal pad is not coupled to the metal line, and wherein any of the first metal pad and the second metal pad is coupled to a package ball.

In accordance with another embodiment, a method for forming a semiconductor device includes: forming an interlayer insulation film over a semiconductor substrate; forming a trench by etching the interlayer insulation film; forming a metal line in the trench, and forming a first metal pad and a second metal pad over the interlayer insulation film in such a manner that the first and second metal pads are spaced apart from the metal line.

The formation of the metal line, the first metal pad, and the second metal pad may include: forming a metal layer over the interlayer insulation film and in the trench; forming mask over the metal layer; and etching the metal layer using the mask pattern as an etch mask.

The method may further include: prior to the formation of the interlayer insulation film, forming a first lower line and a second lower line which are spaced apart from each other over the semiconductor substrate.

The method may further include: simultaneously while forming the trench, forming a contact hole by etching the interlayer insulation film to expose the first lower line and the second lower line, respectively.

The method may further include: prior to the formation of the metal layer, forming a conductive layer over the interlayer insulation film including the trench and the contact hole; and planarizing the conductive layer to expose the interlayer insulation film, to form a first metal contact and a second metal contact—the contact hole; and forming a third metal contact in the trench.

The mask pattern may be formed to expose the metal layer filled in the trench and to cover the first metal pad and the second metal pad.

The method may further include: after the formation of the metal line, the first metal pad and the second metal pad, forming an isolation layer over the metal line between the first metal pad and the second metal pad.

The isolation layer may be formed using a High Density Plasma (HDP) process.

The method may further include: after the formation of the isolation layer, forming a passivation layer over the isolation layer.

The passivation layer may include a Polymide Isoindro Quirazorindione (PIQ) layer.

The method may further include: after the formation of the passivation layer, forming a bonding region by etching the isolation layer to expose an end of the first metal pad and an end of the second metal pad.

In accordance with another embodiment, a semiconductor module includes: a semiconductor device; a command link for enabling the semiconductor device to receive a control signal from an external controller; and a data link coupled to the semiconductor device so as to transmit data, wherein the semiconductor device includes a first metal pad and a second metal pad spaced apart from each other and provided over an interlayer insulation film of a semiconductor substrate, a trench disposed between the first metal pad and the second metal pad and provided in the interlayer insulation film, and a metal line formed in the trench.

In accordance with another embodiment, a semiconductor system including a semiconductor module and a controller includes: the semiconductor module including a semiconductor device, a command link, and a data line, wherein the semiconductor device include: a first metal pad and a second metal pad spaced apart from each other and provided over an interlayer insulation film of a semiconductor substrate, a trench disposed between the first metal pad and the second metal pad and provided in the interlayer insulation film, and a metal line formed in the trench.

In accordance with another aspect of the embodiment, an electronic unit including a semiconductor system and a processor includes: the semiconductor system including a semiconductor module and a controller, wherein the semiconductor module includes a semiconductor device, a command link, and a data link, and wherein the semiconductor device includes a first metal pad and a second metal pad spaced apart from each other and provided over an interlayer insulation film of a semiconductor substrate, a trench disposed between the first metal pad and the second metal pad and provided in the interlayer insulation film, and a metal line formed in the trench.

The processor may include a Central Processing Unit (CPU) and a Graphics Processing Unit (GPU).

The CPU may include a computer or a mobile device.

The GPU may include a graphic device.

In accordance with another embodiment, an electronic system including an electronic unit and an interface includes: the electronic unit including a semiconductor system and a processor, wherein the semiconductor system includes a semiconductor module and a controller, and the semiconductor module includes a semiconductor device, a command link, and a data link, and wherein the semiconductor device includes a first metal pad and a second metal pad spaced apart from each other and provided over an interlayer insulation film of a semiconductor substrate, a trench disposed between the first metal pad and the second metal pad and provided in the interlayer insulation film, and a metal line formed in the trench. The interface may include a monitor, a keyboard, a pointing device (mouse), a USB, a display or a speaker.

It is to be understood that both the foregoing general description and the following detailed description of embodiments are exemplary and explanatory and are intended to provide further explanation of the invention as claimed.

### BRIEF DESCRIPTION OF THE DRAWINGS

FIG. 1 is a cross-sectional view illustrating a conventional semiconductor device according to the related art.

FIG. 2 is a cross-sectional view illustrating a semiconductor device according to an embodiment.

FIG. 3 is a cross-sectional view illustrating a package ball bonded to the semiconductor device according to an embodiment.

FIGS. 4a to 4f are cross-sectional views illustrating a method for forming a semiconductor device according to an embodiment.

FIG. 5 is a block diagram illustrating a semiconductor module according to an embodiment.

FIG. 6 is a block diagram illustrating a semiconductor system according to an embodiment.

FIG. 7 is a block diagram illustrating an electronic unit according to an embodiment.

FIG. 8 is a block diagram illustrating an electronic system according to an embodiment.

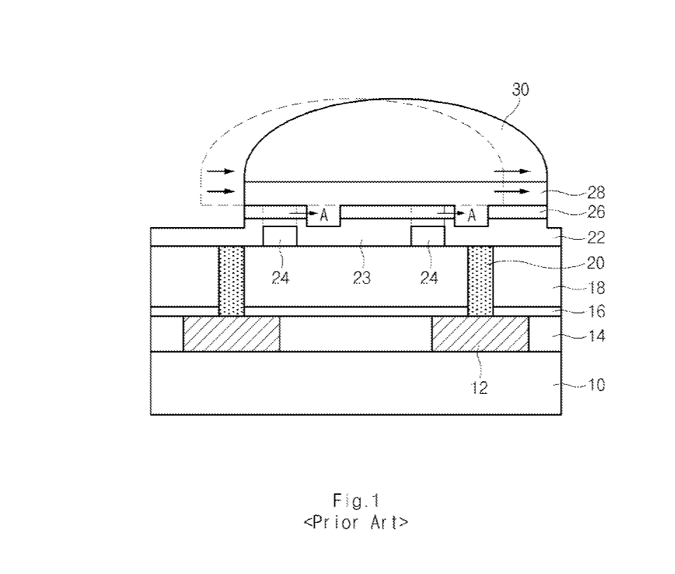

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts.

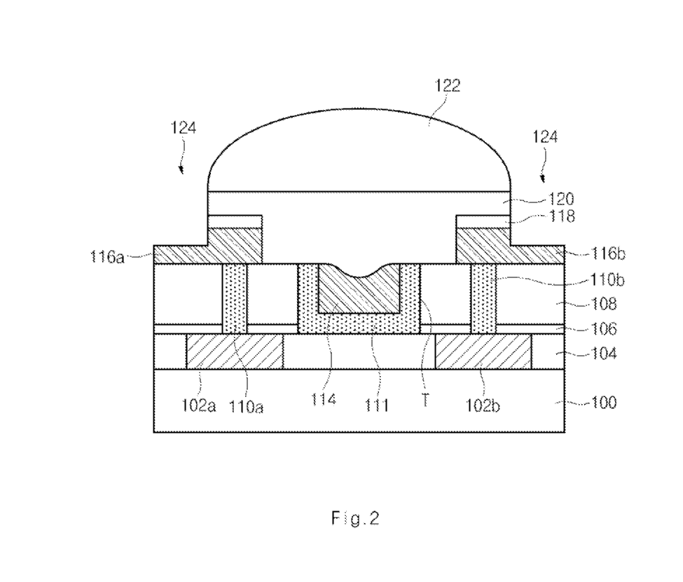

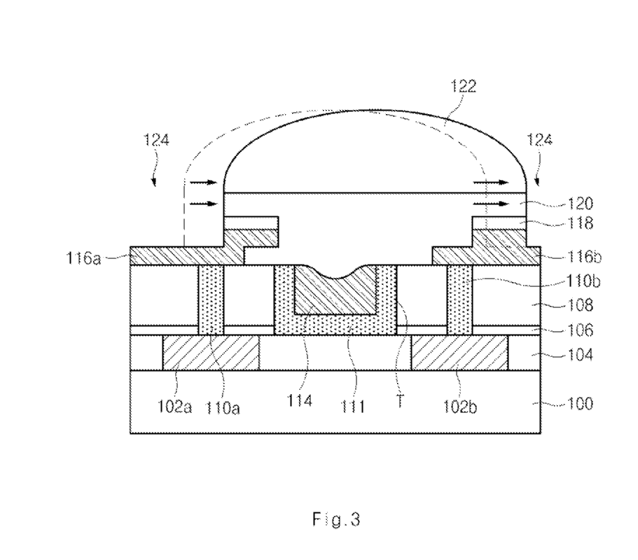

FIG. 2 is a cross-sectional view illustrating a semiconductor device according to an embodiment. FIG. 3 is a cross-sectional view illustrating a package ball bonded to the semiconductor device according to an embodiment.

Referring to FIG. 2, the semiconductor device according to the embodiment includes (i) a first metal pad 116a and a second metal pad 116b that are spaced apart from each other and provided over an interlayer insulation film 108, (ii) a trench T disposed between the first metal pad 116a and the second metal pad 116b and formed in the interlayer insulation film 108, and (iii) a metal line 114 formed in the trench T.

The semiconductor device may further include an isolation layer 120 formed over the metal line 114 and formed between the first metal pad 116a and the second metal pad 116b. In addition, the semiconductor device may further include protective layers 118 that are formed between the isolation layer 120 and a top surface of each of the first metal pad 116a and the second metal pad 116b. In this case, the semiconductor device may further include a first metal contact 110a formed to pass through the interlayer insulation film 108 and coupled to a lower part of the first metal pad 116a; and a second metal contact 110a formed to pass through the interlayer insulation film 108 and coupled to a lower part of the second metal pad 116b.

The semiconductor device may further include a first lower line 102a connected to a lower part of the first metal contact 110a; and a second lower line 102b connected to a lower part of the second metal contact 110b. In addition, the semiconductor device may further include a planarized interlayer insulation film 104 provided between the first lower line 102a and the second lower line 102b; and a protective layer 106 formed over the interlayer insulation film 104.

The semiconductor device may further include a third metal contact 111 disposed between the metal line 114 and an surface of the trench T. The isolation layer 120 may include an insulation film such as a High Density Plasma (HDP) film. A passivation layer 122 may be formed over the isolation layer 120. The passivation layer 122 may include a Polymide Isoindro Quirazorindione (PIQ).

The semiconductor device may further include a bonding region 124 configured to at least partially expose the first metal pad 116a and the second metal pad 116b and formed at both sides of the isolation layer 120.

As described above, the metal line 114, the first and second metal pads 116a, 116b of the semiconductor device are spaced apart from each other by the isolation layer 120, and are formed at different levels, such that the semiconductor device can reduce short-circuiting between the metal line 114, the first and second metal pads 116a, 116b even when the isolation layer 120, the first and second metal pads 116a, 116b are pushed toward the metal line 114 by a pressure generated when a package ball is bonded to the bonding region 124.

FIG. 3 is a cross-sectional view illustrating the package ball bonded to the semiconductor device according to an embodiment.

Referring to FIG. 3, if the package ball is bonded to the bonding region 124, a pressure is imposed in arrow directions, such that the isolation 120 is shifted. However, the metal line 114 is prevented from being short-circuited to the first metal pad 116 because the metal line 114 and the first metal pad 116a are formed at different levels. In addition, the isolation layer 120 is formed between the first metal pad 116a and the second metal pad 116b and over the metal line 114 without interruption by the metal line 114.

Accordingly, the semiconductor device according to the embodiment can prevent the isolation layers 120 from being interrupted by the metal line 114 and, at the same time, can also prevent the metal line 114 from coming into short circuit with the first metal pad 116a.

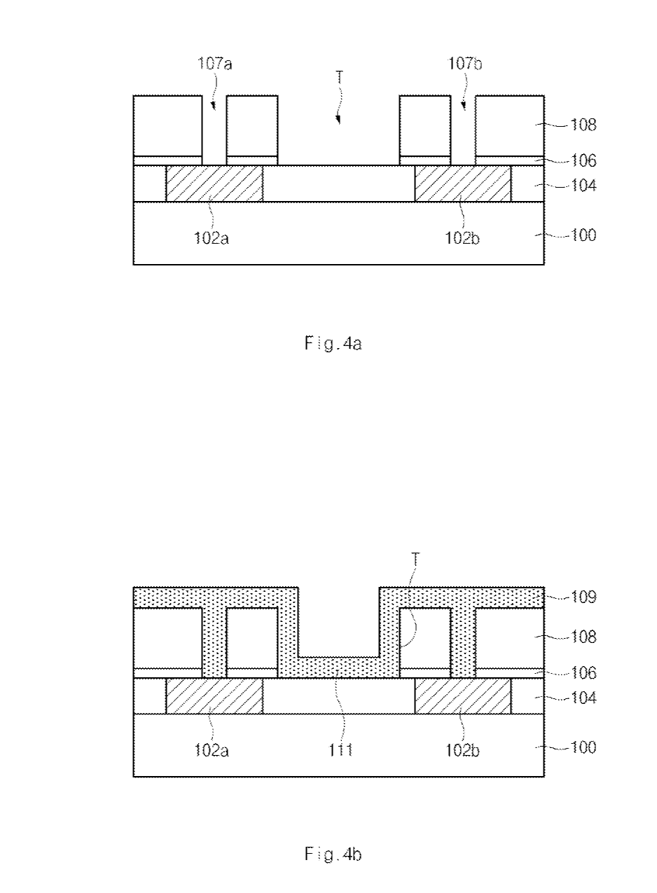

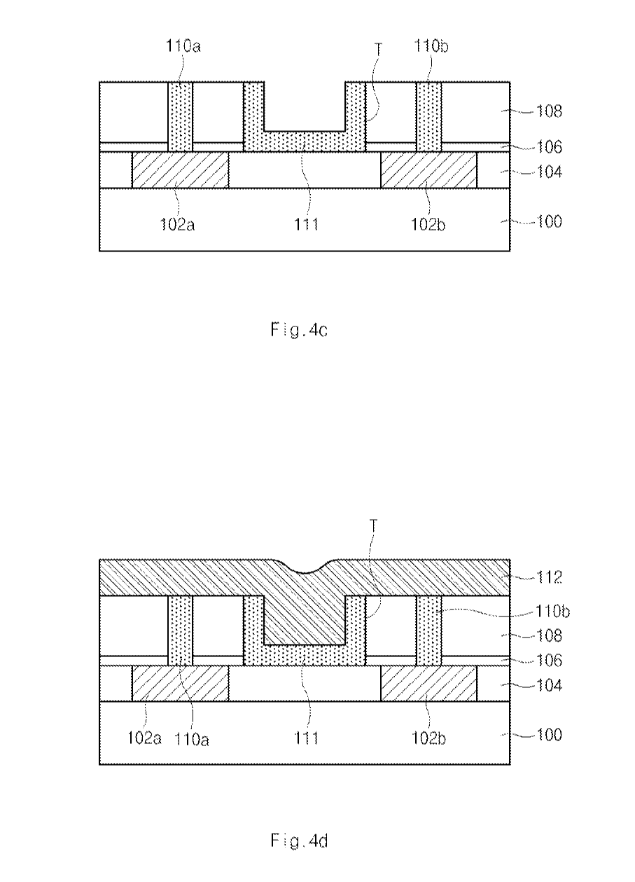

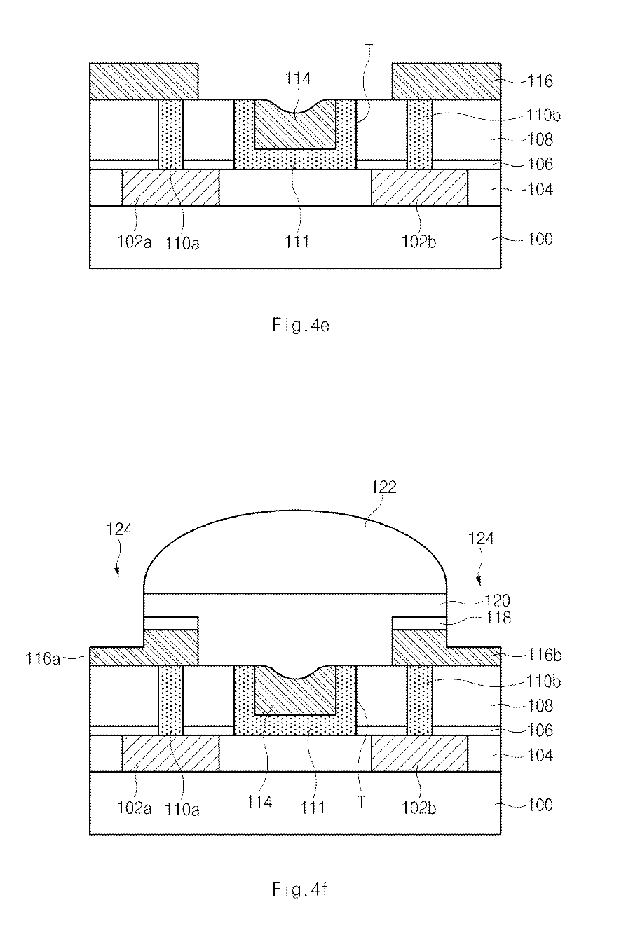

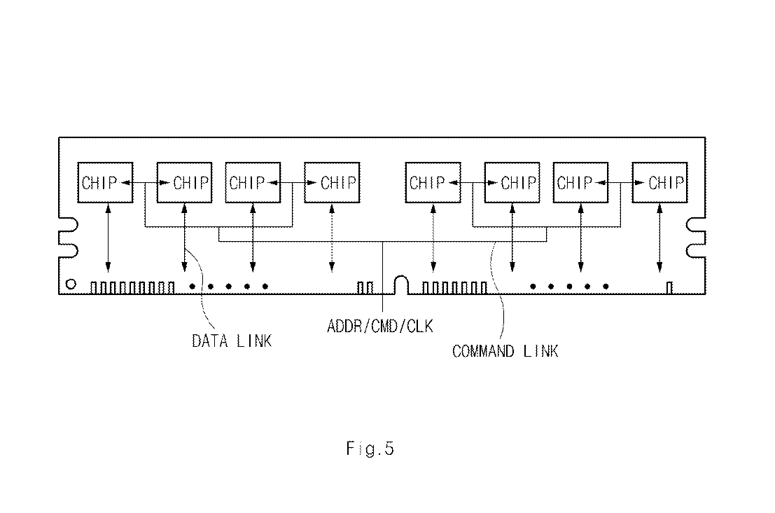

FIGS. 4a to 4f are cross-sectional views illustrating a method for forming the semiconductor device according to embodiments.

Referring to FIG. 4a, a first lower line 102a and a second lower line 102b are formed over a semiconductor substrate 100. Subsequently, a planarization process such as Chemical Mechanical Polishing (CMP) is performed in a manner that a specific portion between the first lower line 102a and the second lower line 102b is filled and upper portions of the first lower line 102a and the second lower line 102b are exposed, resulting in formation of the interlayer insulation film 104.

Thereafter, a protective layer 106 is formed over the interlayer insulation film 104, and an interlayer insulation film 108 is formed over the protective layer 106. Subsequently, the interlayer insulation film 108 is etched to expose the lower line 102 in a manner that a first contact hole 107a and a second contact hole 107b are formed, The interlayer insulation film 108 and the protective layer 106 interposed between the first contact hole 107a and the second contact hole 107b are selectively etched, so that a trench T is formed between the first and the second contact holes 107a-b.

Referring to FIG. 4b, a metal layer 109 is formed over the interlayer insulation film 108. The first and second contact hole 107a, 107b is filled with the conductive layer 109, and the conductive layer 109 is formed in the trench T, e.g., in a liner type.

Referring to FIG. 4c, the planarization process such as CMP is performed against the conductive layer 109 to expose the interlayer insulation film 108, such that not only the first metal contact 110a and the second metal contact 110b are configured to fill the contact hole, but also a third metal contact 111 is formed in the trench T.

Referring to FIG. 4d, a metal layer 112 is formed over the interlayer insulation film 108. In this case, the trench T is filled with the metal layer 112.

Referring to FIG. 4e, after a mask pattern (not shown) is formed to open a trench formed in the metal layer 112, the metal layer 112 is etched using the mask pattern (not shown) as an etch mask. As a result, first metal pad and second metal pad are formed at a specific portion which was covered with the mask pattern (not shown). In addition, the metal layer 112 which was covering the trench T is exposed by the mask pattern (not shown) to form a metal line 114.

In more detail, the first metal pad 116a connected to the first metal contact 110a and the second metal pad 116b connected to the second metal contact 110b are formed over the interlayer insulation film 108. The metal layer 112 filled in the trench T is partially etched to form the metal line 114 at least partially filling in the trench T.

Referring to FIG. 4f, a protective layer 118 is formed over the first metal pad 116a and the second metal pad 116b. An isolation layer 120 is formed not only over the protective layer 118 but also over the metal line 114 and is also formed between the first metal pad 116a and the second metal pad 116b. The isolation layer 120 may include an insulation film formed using a High Density Plasma (HDP) process. Subsequently, a passivation layer 122 protecting the chip is formed over the isolation layer 120, and one end of each the first metal pad 116a and the second metal pad 116b are opened so that a bonding region 124 is formed. In this case, a package ball is bonded to the bonding region 124.

As described above, the semiconductor device according to the embodiment forms the isolation pattern 120 in such a manner of continuously extending between neighboring metal pads 116a-b and thus prevents the isolation pattern 120 from being interrupted by the metal line 114. In addition, even if a bonding pressure is generated when the package ball is bonded to the bonding region, short-circuiting between the metal pads 116 and the metal line 114 can be prevented.

FIG. 5 is a circuit diagram illustrating a semiconductor module according to one embodiment.

Referring to FIG. 5, a semiconductor module includes a plurality of semiconductor devices mounted to a module substrate, a command link for enabling each semiconductor device to receive control signals (for example, an address signal (ADDR), a command signal (CMD), a clock signal (CLK)) from an external controller (not shown), and a data link coupled to a semiconductor device so as to transmit data. In this case, the semiconductor elements may be exemplarily implemented as the semiconductor devices shown in FIG. 2. The command link and the data link may be formed to be identical or similar to those of general semiconductor modules. Although eight semiconductor chips are mounted to the front surface of the module substrate shown in FIG. 5, the semiconductor chips can also be mounted to the back surface of the module substrate. That is, the semiconductor chips can be mounted to one side or both sides of the module substrate, and the number of mounted semiconductor chips is not limited to that shown in FIG. 2. In addition, a material or structure of the module substrate is not limited to those of FIG. 2, and the module substrate may also be formed of other materials or structures.

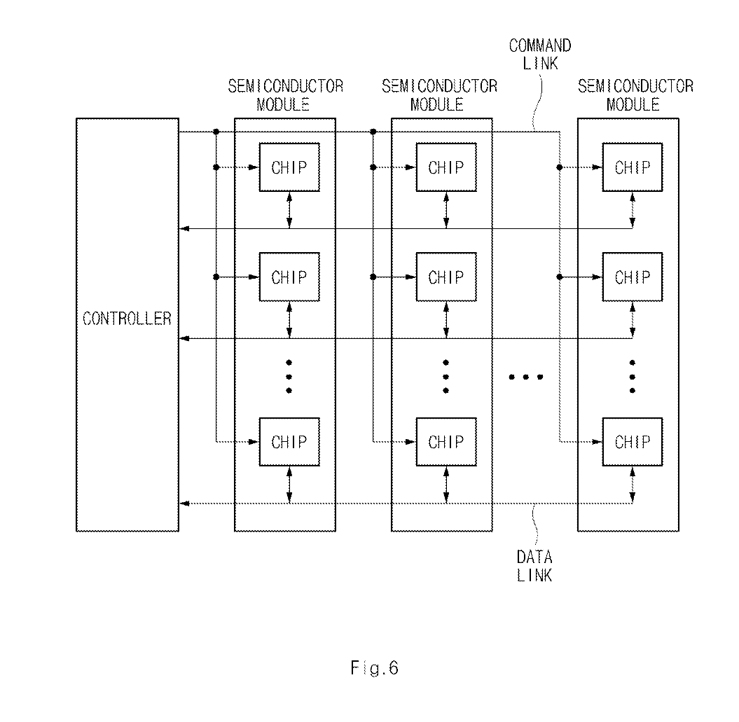

FIG. 6 is a block diagram illustrating a semiconductor system according to an embodiment. Referring to FIG. 6, the semiconductor system includes at least one semiconductor module including a plurality of semiconductor chips, and a controller for providing a bidirectional interface between each semiconductor module and an external system (not shown) so as to control the operations of the semiconductor module. In addition, the semiconductor system may further include a command link and a data link that are configured to electrically interconnect the semiconductor module and the controller. The processor may be identical or similar in function to a controller for controlling a plurality of semiconductor modules for use in a general data processing system, and as such a detailed description thereof will herein be omitted for convenience of description. In one embodiment, the semiconductor device may be, for example, a semiconductor device shown in FIG. 2, and the semiconductor module may be, for example, a semiconductor module shown in FIG. 5.

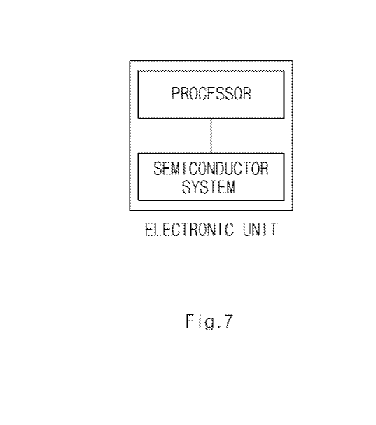

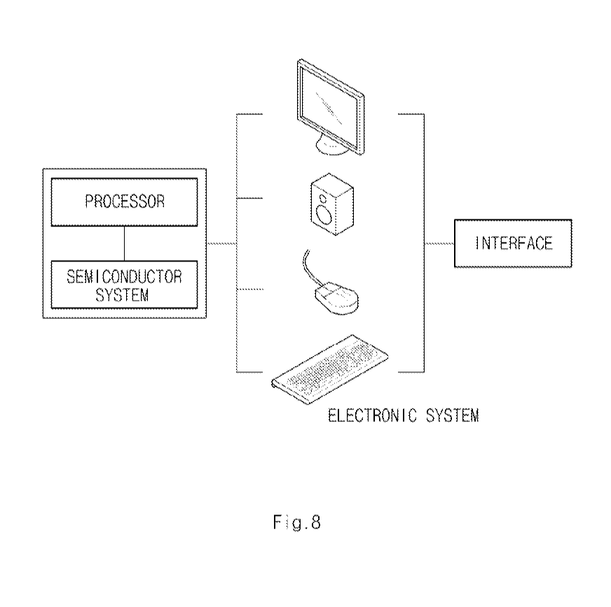

FIG. 7 is a block diagram illustrating an electronic unit according to an embodiment. Referring to FIG. 7, the electronic unit includes a semiconductor system and a processor electrically coupled to the semiconductor system. The semiconductor system may be the same as that of FIG. 6. In an embodiment, the processor may include a Central Processing Unit (CPU), a Micro Processor Unit (MPU), a Micro Controller Unit (MCU), a Graphics Processing Unit (GPU), and a Digital Signal Processor (DSP).

In an embodiment, the CPU or MPU is configured in the form of a combination of an Arithmetic Logic Unit (ALU) serving as an arithmetic and logical operation unit and a Control Unit (CU) for controlling each unit by reading and interpreting a command. If the processor is a CPU or MPU, the electronic unit may include a computer or a mobile device. In addition, the GPU is used to calculate numbers having decimal points, and corresponds to a process for generating graphical data in real-time. If the processor is a GPU, the electronic unit may include a graphic device. In addition, DSP involves converting an analog signal (e.g., voice signal) into a digital signal at a high speed, using the calculated result, re-converting the digital signal into an analog signal, and using the re-converted result. The DSP mainly calculates a digital value. If the processor is a DSP, the electronic unit may include a sound and imaging device.

In an embodiment, the processor may include an Accelerate Calculation Unit (ACU), and may be configured in the form of a CPU integrated into the GPU, such that it serves as a graphics card.

FIG. 8 is a block diagram illustrating an electronic system according to an embodiment. Referring to FIG. 8, an electronic system may include one or more interfaces electrically coupled to the electronic unit. The interface may include a monitor, a keyboard, a pointing device (mouse), a USB, a display or a speaker. However, the scope of the interface is not limited thereto and includes other examples or modifications.

As is apparent from the above description, the semiconductor device and the method for forming the same according to the embodiments form a metal pad and a metal line at different integration levels in such a manner that the metal pad and the metal line are doubly separated from each other by the level difference and by the isolation layer. Thus, short-circuiting between the metal pad and the metal line is prevented although the isolation layer is dislocated by a bonding pressure.

Those skilled in the art will appreciate that embodiments may be carried out in other specific ways than those set forth herein without departing from the spirit and essential characteristics of the embodiment. The above exemplary embodiments are therefore to be construed in all aspects as illustrative and not restrictive.

The above embodiments are illustrative and not limitative. Various alternatives and equivalents are possible. The embodiments are not limited by the type of deposition, etching polishing, and patterning steps described herein. Nor are the embodiments limited to any specific type of semiconductor device. For example, the embodiments may be implemented in a dynamic random access memory (DRAM) device or non-volatile memory device.

What is claimed is:

1. A semiconductor device comprising:
a first metal pad and a second metal pad spaced apart from each other and provided over an interlayer insulation film of a semiconductor substrate;
a trench disposed between the first metal pad and the second metal pad and provided in the interlayer insulation film; and
a metal line formed in the trench.

2. The semiconductor device according to claim 1, the device further comprising:
an isolation layer formed over the metal line and disposed between the first metal pad and the second metal pad.

3. The semiconductor device according to claim 1, the device further comprising:
a first metal contact formed to pass through the interlayer insulation film and coupled to the first metal pad.

4. The semiconductor device according to claim 1, the device further comprising:
a second metal contact formed to pass through the interlayer insulation film and coupled to the second metal pad.

5. The semiconductor device according to claim 2, the device further comprising:
a first lower line connected to a lower part of the first metal contact.

6. The semiconductor device according to claim 1, the device further comprising:
a second lower line coupled to a lower portion of the second metal contact.

7. The semiconductor device according to claim 1, the device further comprising:
a third metal contact formed between the metal line and a surface of the trench.

8. The semiconductor device according to claim 2, wherein the isolation layer includes an insulation film formed using a High Density Plasma (HDP) process.

9. The semiconductor device according to claim 2, the device further comprising:
a passivation layer formed over the isolation layer.

10. The semiconductor device according to claim 9, wherein the passivation layer includes a Polymide Isoindro Quirazorindione (PIQ) layer.

11. The semiconductor device according to claim 2, the device further comprising:
a bonding region formed to expose an end of the first metal pad and an end of the second metal pad and provided at both sides of the isolation layer.

12. The semiconductor device of claim 1,
wherein each of the first metal pad and the second metal pad is provided at a different level from a metal line,
wherein each of the first metal pad and the second metal pad is not coupled to the metal line, and
wherein any of the first metal pad and the second metal pad is coupled to a package ball.

13. A method for forming a semiconductor device comprising:
forming an interlayer insulation film over a semiconductor substrate;
forming a trench by etching the interlayer insulation film;
forming a metal line in the trench; and
forming a first metal pad and a second metal pad over the interlayer insulation film in such a manner that the first and second metal pads are spaced apart from the metal line.

14. The method according to claim 13, wherein the formation of the metal line, the first metal pad, and the second metal pad includes:
forming a metal layer over the interlayer insulation film and in the trench;
forming a mask pattern over the metal layer; and
etching the metal layer using the mask pattern as an etch mask.

15. The method according to claim 14, the method further comprising:
prior to the formation of the interlayer insulation film, forming a first lower line and a second lower line, which are spaced apart from each other, over the semiconductor substrate.

16. The method according to claim 15, the method further comprising:
simultaneously while forming the trench, forming a contact holes by etching the interlayer insulation film to expose the first lower line and the second lower line, respectively.

17. The method according to claim 16, the method further comprising:
prior to the formation of the metal layer, forming a conductive layer over the interlayer insulation film including the trench and the contact hole; and
planarizing the conductive layer to expose the interlayer insulation film to form a first metal contact and a second metal contact in the contact hole; and
forming a third metal contact in the trench.

18. The method according to claim 17, wherein the mask pattern is formed to expose the metal layer filled in the trench and to cover the first metal pad and the second metal pad.

19. The method according to claim 13, the method further comprising:
after the formation of the metal line, the first metal pad, and the second metal pad,
forming an isolation layer over the metal line and between the first metal pad and the second metal pad.

20. The method according to claim 19, wherein the isolation layer is formed using a High Density Plasma (HDP) process.

21. The method according to claim 19, the method further comprising:
after the formation of the isolation layer,
forming a passivation layer over the isolation layer.

22. The method according to claim 21, wherein the passivation layer includes a Polymide Isoindro Quirazorindione (PIQ) layer.

23. The method according to claim 20, the method further comprising:
after the formation of the passivation layer,
forming a bonding region by etching the isolation layer to expose an end of the first metal pad and an end of the second metal pad.

24. A semiconductor module, comprising:
a semiconductor device;
a command link for enabling the semiconductor device to receive a control signal from an external controller; and
a data link coupled to the semiconductor device so as to transmit data,
wherein the semiconductor device includes:
a first metal pad and a second metal pad spaced apart from each other and provided over an interlayer insulation film of a semiconductor substrate;
a trench disposed between the first metal pad and the second metal pad and provided in the interlayer insulation film; and
a metal line formed in the trench.

25. A semiconductor system including a semiconductor module and a controller, comprising:
the semiconductor module including a semiconductor device, a command link, and a data line,
wherein the semiconductor device include:
a first metal pad and a second metal pad spaced apart from each other and provided over an interlayer insulation film of a semiconductor substrate;
a trench disposed between the first metal pad and the second metal pad and provided in the interlayer insulation film; and
a metal line formed in the trench.

26. An electronic unit including a semiconductor system and a processor, comprising:
the semiconductor system including a semiconductor module and a controller,
wherein the semiconductor module includes a semiconductor device, a command link, and a data link, and
wherein the semiconductor device includes
a first metal pad and a second metal pad spaced apart from each other and provided over an interlayer insulation film of a semiconductor substrate;
a trench disposed between the first metal pad and the second metal pad and provided in the interlayer insulation film; and
a metal line formed in the trench.

27. The electronic unit according to claim 26, wherein the processor includes a Central Processing Unit (CPU) and a Graphics Processing Unit (GPU).

28. The electronic unit according to claim 26, wherein the CPU includes a computer or a mobile device.

29. The electronic unit according to claim 26, wherein the GPU includes a graphic device.

30. An electronic system including an electronic unit and an interface, comprising:
the electronic unit including a semiconductor system and a processor,
wherein the semiconductor system includes a semiconductor module and a controller, and
wherein the semiconductor module includes a semiconductor device, a command link, and a data link, and
wherein the semiconductor device includes:
a first metal pad and a second metal pad spaced apart from each other and provided over an interlayer insulation film of a semiconductor substrate;
a trench disposed between the first metal pad and the second metal pad and provided in the interlayer insulation film; and
a metal line formed in the trench.

31. The electronic system according to claim 29, wherein the interface includes a monitor, a keyboard, a pointing device (mouse), a USB, a display or a speaker.
